(19) United States
(12) Patent Application Publication
(10) Pub. No.: US 2026/0072059 A1
(43) Pub. Date: Mar. 12, 2026

(54) SENSOR DEVICES AND ASSOCIATED PRODUCTION METHODS

(71) Applicant: Infineon Technologies AG, Neubiberg (DE)

(72) Inventor: Dietmar SPITZER, Völkermarkt (AT)

(21) Appl. No.: 19/309,065

(22) Filed: Aug. 25, 2025

(30) Foreign Application Priority Data
Sep. 6, 2024 (DE) 102024125645.1

(51) Int. Cl. G01R 15/20; G01R 33/00

(52) U.S. Cl. CPC G01R 15/207; G01R 33/0005; G01R 33/0047; G01R 33/0052

(57) ABSTRACT

A sensor device contains a current conductor which is configured to carry an electric current, a differential magnetic field sensor chip which is arranged in an opening of the current conductor and is configured to detect a magnetic field generated by the electric current, and a metal plate that is arranged above the current conductor and above the magnetic field sensor chip.

### CROSS-REFERENCE TO RELATED APPLICATION

This application claims priority to Germany Patent Application No. 102024125645.1 filed on Sep. 6, 2024, the content of which is incorporated by reference herein in its entirety.

### TECHNICAL FIELD

The present disclosure relates to sensor devices and methods for producing sensor devices.

### BACKGROUND

Magnetic field sensors can be used to measure the intensity of an electric current flowing through a current conductor. For this purpose, the strength of a magnetic field induced by the electric current at the location of the magnetic field sensor should be sufficiently large. One possibility for achieving this is for example to reduce the size of a cross section of the current conductor at the location of the magnetic field sensor. However, a smaller conductor cross section may lead to an increased power loss of the magnetic field sensor.

Manufacturers and developers of sensor devices are constantly striving to improve their products. It may be of particular interest in this case to increase the measurement accuracy of the sensor devices without having to accept increased power losses in the process. In addition, it may be interesting to provide suitable methods for producing such sensor devices.

### SUMMARY

Various aspects relate to a sensor device. The sensor device includes a current conductor which is configured to carry an electric current. The sensor device further includes a differential magnetic field sensor chip which is arranged in an opening of the current conductor and is configured to detect a magnetic field generated by the electric current. The sensor device further includes a metal plate that is arranged above the current conductor and above the magnetic field sensor chip.

Various aspects relate to a method for producing a sensor device. The method includes arranging a current conductor which is configured to carry an electric current. The method further includes arranging a metal plate above the current conductor. The method further includes arranging a differential magnetic field sensor chip in an opening of the current conductor below the metal plate, wherein the magnetic field sensor chip is configured to detect a magnetic field generated by the electric current.

A person skilled in the art will discern further features and advantages of the implementation upon reading the following detailed description and upon examining the attached drawings.

### BRIEF DESCRIPTION OF THE DRAWINGS

The present disclosure is shown in an example and non-limiting manner in the illustrations of the attached drawings, in which identical reference numbers may refer to similar or identical elements. The elements in the drawings are not necessarily depicted to scale in relation to each other. The features of the various examples shown can be combined, provided that they are not mutually exclusive.

FIGS. 1A and 1B respectively show a lateral cross-sectional view and a view from below of a sensor device 100 according to the disclosure.

FIGS. 2A and 2B respectively show the dependence of a magnetic field strength and a phase error of the magnetic field strength on the frequency of an electric measurement current for the case of a sensor device according to the disclosure and for the case of a conventional sensor device.

FIG. 3 shows a flow chart of a method for producing a sensor device according to the disclosure.

### DETAILED DESCRIPTION

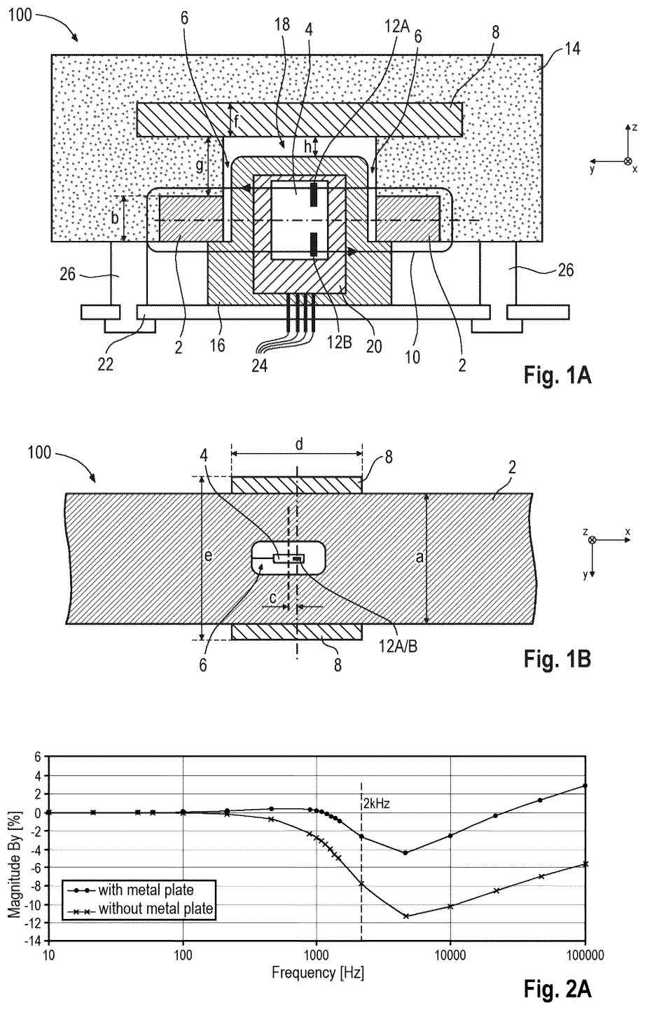

FIGS. 1A and 1B respectively show a lateral cross-sectional view and a view from below of a sensor device 100 according to the disclosure. It should be noted here that, for illustrative reasons, not all of the components of the sensor device 100 described below are illustrated in the view from below of FIG. 1B.

The sensor device 100 may have a current conductor 2, a differential magnetic field sensor chip 4 which is arranged in an opening 6 of the current conductor 2, and a metal plate 8 which is arranged above the current conductor 2 and above the magnetic field sensor chip 4. In the example shown, the current conductor 2 may run in the x direction in a vicinity of the opening 6. The current conductor 2 can be configured to carry an electric current, as a result of which a magnetic field 10 can be generated or induced, the field lines of which can run around the current conductor 2. The magnetic field sensor chip 4 may be configured to detect the magnetic field 10 generated by the electric current.

The differential magnetic field sensor chip 4 can be an integrated circuit or a semiconductor chip, such that reference can also be made to a differential magnetic field sensor IC. The differential magnetic field sensor chip 4 may have a first sensor element 12A and a second sensor element 12B. In the example shown, the two sensor elements 12A and 12B can be spaced apart from one another in the z direction, e.g., they can be arranged on a (straight) line running in the z direction. The two sensor elements 12A and 12B may be sensitive in the y direction, e.g., configured to detect the y component of the magnetic field 10 induced by the electric current at the location of the respective sensor element. Of course, one or both of the sensor elements 12A and 12B may also be sensitive with respect to further spatial directions, for example with respect to the x and/or z direction. Each of the two sensor elements 12A and 12B can generate a signal corresponding to the respectively detected magnetic field component. The electric current carried by the current conductor 2 can be determined by subtracting or summing the two signals (or the two detected magnetic field components). The magnetic field sensor chip 4 can therefore also be referred to as a current sensor or current sensor chip.

The differential magnetic field sensor chip 4 or its sensor elements 12A and 12B are not restricted to a specific sensor technology. In one example, the sensor elements 12A and 12B can correspond to Hall sensor elements. In further examples, the sensor elements 12A and 12B can be magnetoresistive xMR sensor elements, in particular AMR sensor elements, GMR sensor elements or TMR sensor elements. By way of example, each of the sensor elements 12A and 12B per se can be implemented as a resistor bridge having e.g., four resistors. In one example, the resistors can in this case be arranged in the form of a Wheatstone bridge. The sensor elements 12A and 12B can be integrated in a circuit of the magnetic field sensor chip 4. Signal amplification, analog-to-digital conversion, digital signal processing and/or offset and temperature compensation can furthermore take place in such a circuit. Besides the components of the respective sensor element, components for the signal amplification and/or the analog-to-digital conversion may or may not be regarded as part of the sensor elements 12A and 12B.

The current conductor 2 may also be referred to as a busbar and made for example from at least one of copper, aluminum or alloys thereof. The current conductor 2 may have a (in particular constant) dimension a in the y direction in the vicinity of the opening 6, which may be in a range from approximately 12 mm to approximately 20 mm (for example approximately 16 mm) in a non-limiting example. In the z direction, the current conductor 2 may have a dimension b, which may be in a range from approximately 1 mm to approximately 2.5 mm (for example approximately 1.5 mm) in a non-limiting example. In the view from below of FIG. 1B, the opening 6 of the current conductor 2 may have a substantially rectangular shape. In further examples, the opening 6 may have a different shape, for example round, circular, oval, elliptical, square or the like. From the view from below of FIG. 1B, it is apparent that the sensor elements 12A and 12B of the magnetic field sensor chip 4 may be arranged offset from a center of the opening 6. Here, an offset c may lie in a range from approximately 0.5 mm to approximately 1.5 mm (for example approximately 1 mm).

The metal plate 8 may also be referred to as metal lamina, metal sheet, flux plate and made from at least one of copper, aluminum or alloys thereof. By way of example, the metal plate 8 can be produced by a punching process. In the x direction, the metal plate 8 may have a dimension d, which may be in a range from approximately 12 mm to approximately 20 mm (for example approximately 16 mm) in a non-limiting example. In the y direction, the metal plate 8 may have a dimension e, which may be in a range from approximately 15 mm to approximately 25 mm (for example approximately 20 mm) in a non-limiting example. The dimension e of the metal plate 8 in the y direction may be greater than the dimension a of the current conductor 2 in the y direction. Furthermore, the dimension e of the metal plate 8 in the y direction may be greater than the dimension d of the metal plate 8 in the x direction. In the z direction, the metal plate 8 may have a dimension f, which may be in a range from approximately 0.5 mm to approximately 1.5 mm (for example approximately 1 mm) in a non-limiting example. A distance g from the top side of the busbar 2 to the underside of the metal plate 8 may be in a range from approximately 2.5 mm to approximately 5 mm (for example approximately 2.5 mm) in a non-limiting example.

In the example view from below of FIG. 1B, the metal plate 8 can have a rectangular shape. In other examples, the metal plate 8 may have a different shape, for example round, circular, oval, elliptical, square or the like. In the example shown, the corners of the metal plate 8 may be substantially pointed. In further examples, the corners of the metal plate 8 may also be rounded. In the view from below shown, the metal plate 8 can in particular be closed and have no openings. It can be seen from the side view of FIG. 1A that the metal plate 8 can run parallel to the current conductor 2. In the example shown, the metal plate 8 may be formed in a substantially planar manner and essentially run in the x-y plane. In further examples, the metal plate 8 does not necessarily have to be formed in a planar manner, however, but may for example be bent at least partially in the direction of the current conductor 2.

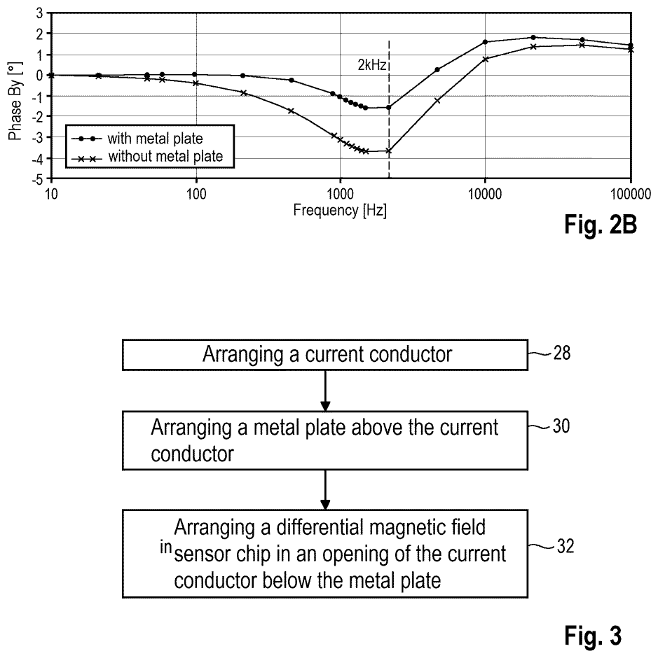

The metal plate 8 may be configured to influence or to change the magnetic field 10 generated by a measurement current. In this context, it should be noted that such an influence of the metal plate 8 on the magnetic field 10 in FIG. 1A or in the field lines of the magnetic field 10 is not taken into account or illustrated for the sake of simplicity. The influence of the metal plate 8 on the magnetic field 10 can decrease at a distance from the metal plate 8. Since the first sensor element 12A may be arranged closer to the metal plate 8 than the second sensor element 12B, an influence of the metal plate 8 on a measurement of the first sensor element 12A may be stronger than on a measurement of the second sensor element 12B. If the distance of the second sensor element 12B from the metal plate 8 is sufficiently large, an influence of the metal plate 8 on the measurement of the second sensor element 12B may even be negligible. As a result, a certain asymmetry in the measurements or measurement results of the two sensor elements 12A and 12B can be provided by the metal plate 8. As a result, a phase error of the measured magnetic field strength can be reduced, as discussed further below in connection with FIGS. 2A and 2B.

The sensor device 100 may have still further components. In the example shown, the current conductor 2 and the metal plate 8 can be encapsulated in a first encapsulation material 14. In this case, the magnetic field sensor chip 4 can be arranged outside the first encapsulation material 14. The magnetic field sensor chip 4 can be encapsulated in a second encapsulation material 16, wherein the current conductor 2 and the metal plate 8 can be arranged outside the second encapsulation material 16. In this case, the current conductor 2 can therefore be an external current conductor which is arranged outside the package which is formed by the second encapsulation material 16. Alternatively to the example shown, the metal plate 8, the current conductor 2, and the magnetic field sensor chip 4 may in further examples be encapsulated in a common encapsulation material.

In a non-limiting example, one or both of the encapsulation materials 14 and 16 may be an epoxy resin which may be made using a suitable molding process. The encapsulation materials 14 and 16 may be the same or differ from one another. The first encapsulation material 14 may have a depression 18, wherein the magnetic field sensor chip 4 or the second encapsulation material 16 with the magnetic field sensor chip 4 encapsulated therein may be arranged in the depression 18. A distance h from the top side of the second encapsulation material 16 to the underside of the metal plate 8 may be in a range from approximately 0.1 mm to approximately 2.6 mm (for example approximately 2.5 mm) in a non-limiting example.

In the example shown, the magnetic field sensor chip 4 may be mounted on a first printed circuit board (or a first PCB) 20. In this case, the printed circuit board 20 can in particular run perpendicularly to the current conductor 2. The first printed circuit board 20 may likewise be encapsulated in the second encapsulation material 16. The package formed by the second encapsulation material 16 may be arranged on a second printed circuit board 22, which may for example be a gate driver PCB. The magnetic field sensor chip 4 may be electrically connected to the second printed circuit board 22 using the first printed circuit board 20 and pins 24. Mounting elements 26, which may also function as spacers, may be arranged between the underside of the first encapsulation material 14 and the top side of the second printed circuit board 22.

As already explained above, the strength By of the y component of the magnetic field 10 can be detected or measured by the magnetic field sensor chip 4. In this context, FIG. 2A shows a dependence of the magnetic field strength By on the frequency of the electric current carried by the current conductor 2 for a first case of a sensor device according to the disclosure having a metal plate 8 (cf. “with metal plate”) and a second case of a conventional sensor device without a metal plate (cf. “without metal plate”). Here, the magnetic field strength By is plotted in percent (based on the initial value at 0 Hz) against the frequency in Hz. FIG. 2B shows a dependence of the phase of the magnetic field strength By (in degrees) on the frequency of the electric current carried by the current conductor 2 (in Hz) for the two aforementioned cases with and without metal plate 8. It can be seen from the frequency responses shown in FIG. 2B that a phase error in a sensor device according to the disclosure may be smaller than in a conventional sensor device. Sensor devices according to the disclosure can thus provide an improved frequency response. Typical frequencies may be in a range from approximately 0 kHz to approximately 2 kHz in one example. In this context, an example typical frequency value of approximately 2 kHz is labeled in each case in FIGS. 2A and 2B.

In conventional sensor devices, the frequency response can be optimized by reducing the busbar width in the sensor region (e.g., by side tapers formed in the current conductor). However, the disadvantage of such a principle can be that the reduced cross section of the current conductor can lead to a higher power loss in the region of the sensor, as a result of which there may be a threat of overheating. In contrast, sensor devices according to the disclosure can achieve a suitable improvement in the frequency response, as described, and dispense with a reduction in the size of the current conductor cross section in the process. As a result, an improved thermal flow through the current conductor and an improved mechanical stability of the current conductor can be provided. Furthermore, sensor devices according to the disclosure may in particular be coreless and need not have a magnetic field concentrator. The sensor devices can be coreless current sensors that can be integrated into an external busbar.

FIG. 3 shows a method for producing a sensor device according to the disclosure. The method is shown in a general form and can be used for example to produce the sensor device 100 of FIGS. 1A and 1B. The method can be extended by one or more aspects which are described in conjunction with other examples described here. The sequence of the individual method steps can be changed as long as this is technically expedient.

In one step 28, it is possible to arrange a current conductor 2, which is configured to carry an electric current. In a further step 30, a metal plate 8 can be arranged above the current conductor 2. In a further step 32, a differential magnetic field sensor chip 4 can be arranged in an opening 6 of the current conductor 2 below the metal plate 8. The magnetic field sensor chip 4 may be configured to detect a magnetic field 10 generated by the electric current.

In a first example, in further optional steps, the current conductor 2 and the metal plate 8 can be encapsulated in a first encapsulation material 14, and the magnetic field sensor chip 4 can be arranged in a depression 18 of the first encapsulation material 14. In a second example, in a further optional step, the metal plate 8, the current conductor 2, and the magnetic field sensor chip 4 can be encapsulated in a common encapsulation material.

### EXAMPLES

Hereinafter, sensor devices according to the disclosure and associated production methods are described using examples.

Example 1 is a sensor device comprising: a current conductor which is configured to carry an electric current; a differential magnetic field sensor chip which is arranged in an opening of the current conductor and is configured to detect a magnetic field generated by the electric current; and a metal plate that is arranged above the current conductor and above the magnetic field sensor chip.

Example 2 is a sensor device according to example 1, wherein: the current conductor runs in a first direction in a vicinity of the opening, the magnetic field sensor chip comprises two sensor elements, including a first sensor element and a second sensor element, that are spaced apart in a second direction perpendicular to the first direction, and the two sensor elements are sensitive in a third direction perpendicular to the first direction and perpendicular to the second direction.

Example 3 is a sensor device according to example 1 or 2, wherein the first sensor element of the magnetic field sensor chip is arranged closer to the metal plate than the second sensor element of the magnetic field sensor chip.

Example 4 is a sensor device according to any one of the preceding examples, wherein the sensor elements of the magnetic field sensor chip are arranged offset from a center of the opening.

Example 5 is a sensor device according to any one of the preceding examples, wherein the metal plate and the current conductor are encapsulated in a first encapsulation material.

Example 6 is a sensor device according to example 5, wherein the magnetic field sensor chip is arranged outside the first encapsulation material.

Example 7 is a sensor device according to example 5 or 6, wherein the first encapsulation material has a depression and the magnetic field sensor chip is arranged in the depression.

Example 8 is a sensor device according to any one of the preceding examples, wherein the magnetic field sensor chip is encapsulated in a second encapsulation material and the current conductor is arranged outside the second encapsulation material.

Example 9 is a sensor device according to any one of examples 1 to 4, wherein the metal plate, the current conductor, and the magnetic field sensor chip are encapsulated in a common encapsulation material.

Example 10 is a sensor device according to any one of the preceding examples, wherein the magnetic field sensor chip is mounted on a printed circuit board and the printed circuit board runs perpendicularly to the current conductor.

Example 11 is a sensor device according to any one of examples 2 to 10, wherein the current conductor has a constant dimension in the third direction in the vicinity of the opening.

Example 12 is a sensor device according to any one of examples 2 to 11, wherein a dimension of the metal plate in the third direction is greater than a dimension of the current conductor in the third direction.

Example 13 is a sensor device according to any one of examples 2 to 12, wherein a dimension of the metal plate in the third direction is greater than a dimension of the metal plate in the first direction.

Example 14 is a sensor device according to any one of the preceding examples, wherein the metal plate has no openings.

Example 15 is a sensor device according to any one of the preceding examples, wherein the metal plate runs parallel to the current conductor.

Example 16 is a sensor device according to any one of examples 1 to 14, wherein the metal plate is at least partially bent in the direction of the current conductor.

Example 17 is a sensor device according to any one of the preceding examples, wherein the metal plate is made from at least one of copper, aluminum or alloys thereof.

Example 18 is a sensor device according to any one of the preceding examples, wherein the sensor device is coreless and does not have a magnetic field concentrator.

Example 19 is a method for producing a sensor device, wherein the method comprises: arranging a current conductor which is configured to carry an electric current; arranging a metal plate above the current conductor; and arranging a differential magnetic field sensor chip in an opening of the current conductor below the metal plate, wherein the magnetic field sensor chip is configured to detect a magnetic field generated by the electric current.

Example 20 is a method according to example 19, furthermore comprising: encapsulating the current conductor and the metal plate in a first encapsulation material; and arranging the magnetic field sensor chip in a depression of the first encapsulation material.

Example 21 is a method according to example 19, furthermore comprising: encapsulating the metal plate, the current conductor, and the magnetic field sensor chip in a common encapsulation material.

It should be pointed out that the description and the drawings only illustrate the principles of the proposed methods and devices. A person skilled in the art will be capable of implementing different arrangements which, although they are not expressly described or shown here, embody the principles of the implementation and are contained within the scope thereof. In addition, all examples and implementations outlined in the present document are intended fundamentally and expressly for explanatory purposes only, in order to help the reader understand the principles of the proposed methods and devices. In addition, all statements in this document that describe principles, aspects and implementations of the implementation and specific examples thereof are also intended to encompass their equivalents.

1. A sensor device, comprising:
a current conductor which is configured to carry an electric current;
a differential magnetic field sensor chip which is arranged in an opening of the current conductor and is configured to detect a magnetic field generated by the electric current; and
a metal plate that is arranged above the current conductor and above the magnetic field sensor chip.

2. The sensor device as claimed in claim 1, wherein:
the current conductor runs in a first direction in a vicinity of the opening,
the magnetic field sensor chip comprises two sensor elements, including a first sensor element and a second sensor element, that are spaced apart in a second direction perpendicular to the first direction, and
the two sensor elements, are sensitive in a third direction perpendicular to the first direction and perpendicular to the second direction.

3. The sensor device as claimed in claim 1, wherein the first sensor element of the magnetic field sensor chip is arranged closer to the metal plate than a the second sensor element of the magnetic field sensor chip.

4. The sensor device as claimed in claim 1, wherein the two sensor elements, of the magnetic field sensor chip are arranged offset from a center of the opening.

5. The sensor device as claimed in claim 1, wherein the metal plate and the current conductor are encapsulated in a first encapsulation material.

6. The sensor device as claimed in claim 5, wherein the magnetic field sensor chip is arranged outside the first encapsulation material.

7. The sensor device as claimed in claim 5, wherein the first encapsulation material has a depression and the magnetic field sensor chip is arranged in the depression.

8. The sensor device as claimed in claim 1, wherein the magnetic field sensor chip is encapsulated in a second encapsulation material and the current conductor is arranged outside the second encapsulation material.

9. The sensor device as claimed in claim 1, wherein the metal plate, the current conductor, and the magnetic field sensor chip are encapsulated in a common encapsulation material.

10. The sensor device as claimed in claim 1, wherein the magnetic field sensor chip is mounted on a printed circuit board and the printed circuit board runs perpendicularly to the current conductor.

11. The sensor device as claimed in claim 2, wherein the current conductor has a constant dimension in the third direction in the vicinity of the opening.

12. The sensor device as claimed in claim 2, wherein a dimension of the metal plate in the third direction is greater than a dimension of the current conductor in the third direction.

13. The sensor device as claimed in claim 2, wherein a dimension of the metal plate in the third direction is greater than a dimension of the metal plate in the first direction.

14. The sensor device as claimed in claim 1, wherein the metal plate has no openings.

15. The sensor device as claimed in claim 1, wherein the metal plate runs parallel to the current conductor.

16. The sensor device as claimed in claim 1, wherein the metal plate is at least partially bent in the direction of the current conductor.

17. The sensor device as claimed in claim 1, wherein the metal plate is made from at least one of copper, aluminum or alloys thereof.

18. The sensor device as claimed in claims, claim 1 wherein the sensor device is coreless and does not have a magnetic field concentrator.

19. A method for producing a sensor device, wherein the method comprises:
arranging a current conductor which is configured to carry an electric current;
arranging a metal plate above the current conductor; and
arranging a differential magnetic field sensor chip in an opening of the current conductor below the metal plate, wherein the magnetic field sensor chip is configured to detect a magnetic field generated by the electric current.

20. The method as claimed in claim 19, furthermore comprising:
encapsulating the current conductor and the metal plate in a first encapsulation material; and
arranging the magnetic field sensor chip in a depression of the first encapsulation material.

21. The method as claimed in claim 19, furthermore comprising:
encapsulating the metal plate, the current conductor, and the magnetic field sensor chip in a common encapsulation material.
